(19) United States
(12) Patent Application Publication
(10) Pub. No.: US 2025/0285995 A1
(43) Pub. Date: Sep. 11, 2025

(54) PROTECTIVE BARRIER FOR ELECTROSTATIC DISCHARGE CONTACT STRUCTURE

(71) Applicant: Micron Technology, Inc., Boise, ID (US)

(72) Inventors: Seng Kim YE, Singapore (SG); Hong Wan NG, Singapore (SG); Gokul KUMAR, Dublin, CA (US); Chin Hui CHONG, Singapore (SG); Kelvin Aik Boo TAN, Singapore (SG)

(21) Appl. No.: 19/045,130

(22) Filed: Feb. 4, 2025

Related U.S. Application Data
(60) Provisional application No. 63/563,820, filed on Mar. 11, 2024.

(51) Int. Cl. H01L 23/60; H01L 21/56; H01L 25/065

(52) U.S. Cl. CPC H01L 23/60; H01L 21/56; H01L 25/0657; H01L 2225/06562

(57) ABSTRACT

Implementations described herein relate to various semiconductor device assemblies. In some implementations, an apparatus includes an integrated circuit and an electrostatic discharge contact structure that is proximate to an outer edge of the apparatus and that is electrically-coupled with the integrated circuit. The electrostatic discharge contact structure includes a first material that is electrically-conductive and has a first corrosion rate in an environment surrounding the apparatus. The apparatus further includes a protective barrier that is proximate to the electrostatic discharge contact structure and that seals at least a portion of the electrostatic discharge contact structure from the environment. The protective barrier includes second material that is electrically-conductive and has a second corrosion rate in the environment that is less than the first corrosion rate.

### CROSS-REFERENCE TO RELATED APPLICATION

This Patent Application claims priority to U.S. Provisional Patent Application No. 63/563,820, filed on Mar. 11, 2024, entitled “PROTECTIVE BARRIER FOR ELECTROSTATIC DISCHARGE CONTACT STRUCTURE,” and assigned to the assignee hereof. The disclosure of the prior Application is considered part of and is incorporated by reference into this Patent Application.

### TECHNICAL FIELD

The present disclosure generally relates to semiconductor devices and methods of forming semiconductor devices. For example, the present disclosure relates to a protective barrier for an electrostatic discharge (ESD) contact structure.

### BACKGROUND

A semiconductor package may include a semiconductor substrate, one or more semiconductor electronic components coupled to and/or embedded in the semiconductor substrate, and a casing formed over the semiconductor substrate to encapsulate the one or more semiconductor electronic components. The one or more semiconductor electronic components may be interconnected by electrical interconnects to form one or more semiconductor devices, such as one or more integrated circuits (ICs) (e.g., one or more dies or chips). For example, the semiconductor electronic components and the electrical interconnects may be fabricated on a semiconductor wafer to form one or more ICs before being diced into dies or chips and then packaged. A semiconductor package may be referred to as a semiconductor chip package that includes one or more ICs. A semiconductor package protects the semiconductor electronic components and the electrical interconnects from damage and includes a mechanism for connecting the semiconductor electronic components and the electrical interconnects to external components (e.g., a circuit substrate), such as via balls, pins, leads, contact pads, or other electrical interconnect structures. A semiconductor device assembly may be or may include a semiconductor package, multiple semiconductor packages, and/or one or more components of a semiconductor package (e.g., one or more semiconductor devices with or without a casing).

An electronic system assembly may include multiple semiconductor packages electrically coupled to a carrier substrate (e.g., circuit substrate). An electronic system assembly may include additional system components electrically coupled to the carrier substrate. The carrier substrate may include electrical interconnects and conductive paths used for interconnecting system components, including the multiple semiconductor packages and other system components of the electronic system assembly. Accordingly, the multiple semiconductor packages may be electrically connected to each other and/or to one or more additional system components via the carrier substrate to form the electronic system assembly. By way of example, other system components may include passive components (e.g., storage capacitors), processing units (e.g., a central processing unit (CPU), a graphics processing unit (GPU), a microprocessor, and/or a microcontroller), control units (e.g., a microcontroller, a memory controller, and/or a power management controller), or one or more other electronic components.

### BRIEF DESCRIPTION OF THE DRAWINGS

FIGS. 1A and 1B are diagrams of an example apparatus that may be manufactured using techniques described herein.

FIG. 2 is a diagram of an example memory device that may be manufactured using techniques described herein.

FIG. 3 is a flowchart of an example method of forming a substrate having an ESD contact structure and a protective barrier described herein.

FIG. 4 is a flowchart of an example method associated with a protective barrier for an ESD contact structure described herein.

FIG. 5 is a flowchart of an example method of forming a memory device having a protective barrier for an ESD contact structure described herein.

FIG. 6 is a diagram of an example implementation of a protective barrier for an ESD contact structure described herein.

FIGS. 7A and 7B are diagrams of an example implementation of a protective barrier for an ESD contact structure described herein.

FIG. 8 includes an example series of semiconductor manufacturing operations that may be performed to form a protective barrier for an ESD contact structure described herein.

### DETAILED DESCRIPTION

Electrostatic discharge (ESD) in semiconductors refers to the sudden and unintended flow of electric current between two objects with different electric potentials, often resulting in damage to sensitive electronic components. Integrated circuit (IC) devices (e.g., semiconductor devices), crucial components in electronic devices, are particularly susceptible to ESD due to their miniaturized size and intricate circuitry. When the IC device (or a semiconductor package including the IC device) accumulates an electrostatic charge, through manufacturing and/or handling, the accumulated electrostatic charge can discharge rapidly, generating a high voltage that exceeds the IC device's tolerance levels. This discharge can lead to the breakdown of the insulating layers within the IC device, causing permanent damage or degradation.

A semiconductor package including the IC device may include an ESD protection system that is capable of discharging the accumulated electrostatic charge during assembly and/or handling of the semiconductor package. Discharging the accumulated electrostatic charge may protect the IC device from damage.

The ESD protection system may include a combination of ESD protection circuitry on the IC device, interconnects and/or traces within the semiconductor package, and an ESD contact structure that is proximate an outer sidewall of the semiconductor package. In order to be capable of discharging the accumulated electrostatic charge, the ESD contact structure may be exposed to an environment surrounding the semiconductor package.

In some cases, exposure of the ESD contact structure to the environment may cause corrosion (e.g., oxidation) to surfaces of the ESD contact structure, and inhibit an ability of the ESD contact structure to discharge the accumulated electrostatic charge. Further, and in some cases, the ESD contact structure may include a material that is prone to electromigration. Electromigration is a phenomenon in which the flow of high-density electrical currents causes a gradual movement of metal atoms and/or ions within the conductive paths of the IC device, leading to the potential degradation and eventual failure of the IC device. The negative impact of electromigration includes the formation of voids, hillocks, and structural damage to the ESD contact structure, which can result in open circuits or shorts, compromising the reliability and functionality of the IC device over time.

Some implementations described herein include a semiconductor package including an IC device (e.g., a semiconductor die) and an ESD contact structure proximate an outer sidewall of the semiconductor package. The semiconductor package includes a protective barrier that safeguards the ESD contact structure from an environment surrounding the semiconductor package.

In this way, the ESD contact structure is protected from corrosion (e.g., oxidation) and/or electromigration that may inhibit a capability of the ESD contact structure to discharge an accumulated electrostatic charge during assembly and/or handling of the semiconductor package. By protecting the ESD contact structure, a likelihood of damage to the IC device is reduced, to improve a quality and/or a reliability of the semiconductor package. As a result, an amount of resources used to support a market consuming the semiconductor package including the IC device (e.g., raw materials, labor, semiconductor manufacturing tools, and/or computing resources) is reduced.

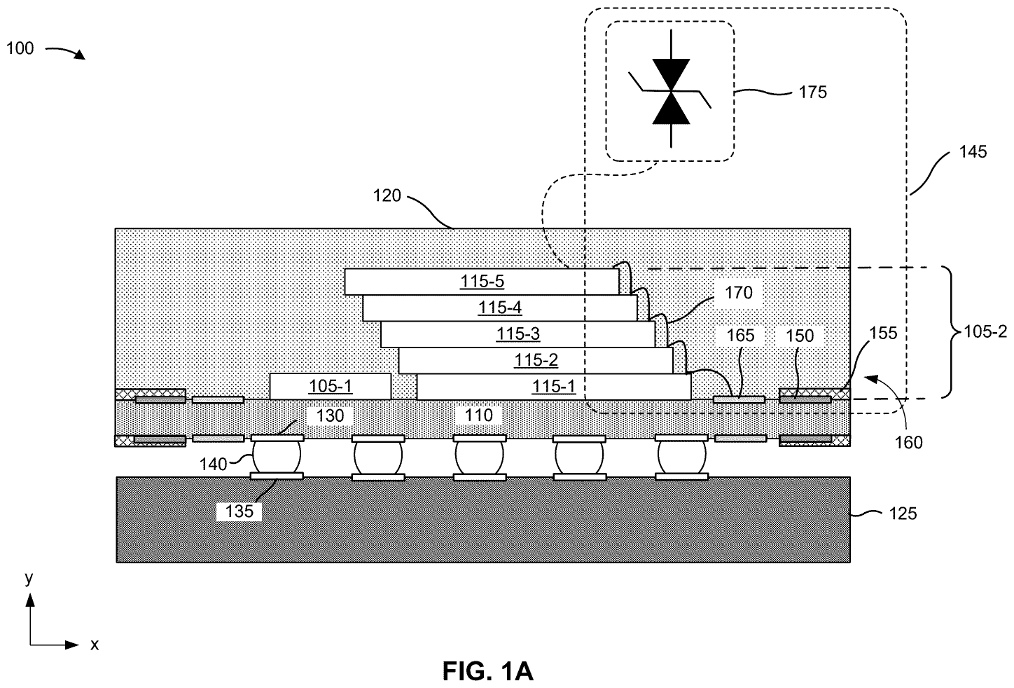

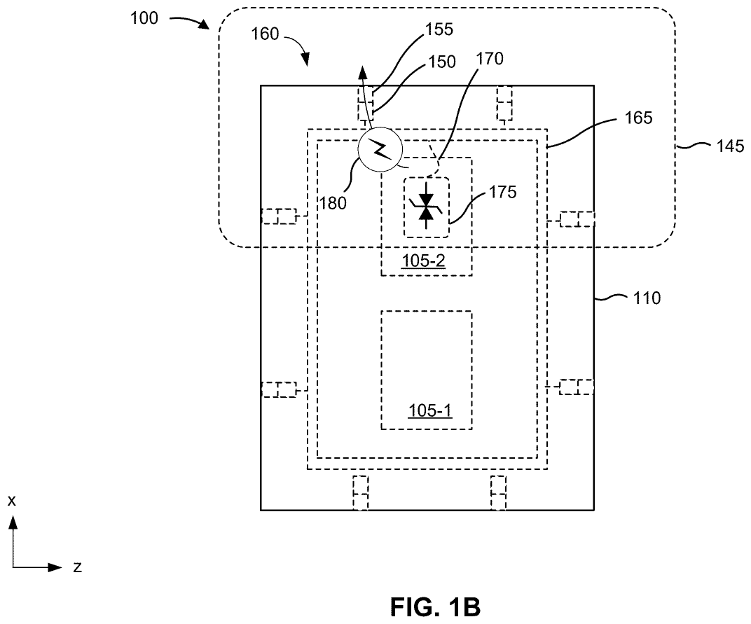

FIGS. 1A and 1B are diagrams of an example apparatus 100 that may be manufactured using techniques described herein. The apparatus 100 may include any type of device or system that includes one or more integrated circuits 105. For example, the apparatus 100 may include a memory device, a flash memory device, a NAND memory device, a NOR memory device, a random access memory (RAM) device, a read-only memory (ROM) device, a dynamic RAM (DRAM) device, a static RAM (SRAM) device, a solid state drive (SSD), a microchip, and/or a system on a chip (SoC), among other examples. In some cases, the apparatus 100 may be referred to as a semiconductor package, an assembly, a semiconductor device assembly, or an integrated assembly.

As shown in FIG. 1A, the apparatus 100 may include one or more integrated circuits 105, shown as a first integrated circuit 105-1 and a second integrated circuit 105-2, disposed on a substrate 110. An integrated circuit 105 may include any type of circuit, such as an analog circuit, a digital circuit, a radiofrequency (RF) circuit, a power supply, a power management circuit, an input-output (I/O) chip, an application-specific integrated circuit (ASIC), a field-programmable gate array (FPGA), and/or a memory device (e.g., a NAND memory device, a NOR memory device, a RAM device, or a ROM device). An integrated circuit 105 may be mounted on or otherwise disposed on a surface of the substrate 110. Although the apparatus 100 is shown as including two integrated circuits 105 as an example, the apparatus 100 may include a different number of integrated circuits 105.

In some implementations, an integrated circuit 105 may include a single semiconductor die 115 (sometimes called a die), as shown by the first integrated circuit 105-1. In some implementations, an integrated circuit 105 may include multiple semiconductor dies 115 (sometimes called dies), as shown by the second integrated circuit 105-2, which is shown as including five semiconductor dies 115-1 through 115-5.

As shown in FIG. 1A, for an integrated circuit 105 that includes multiple dies 115, the dies 115 may be stacked on top of each other to reduce a footprint of the apparatus 100. In some implementations, a spacer may be present between dies 115 that are adjacent to one another in the stack to enable electrical separation and heat dissipation. The stacked dies 115 may include three-dimensional electrical interconnects, such as through-silicon vias (TSVs), to route electrical signals between dies 115. Although the integrated circuit 105-2 is shown as including five dies 115, an integrated circuit 105 may include a different number of dies 115 (e.g., at least two dies 115). A first die 115-1 (sometimes called a bottom die or a base die) may be disposed on the substrate 110, a second die 115-2 may be disposed on the first die 115-1, and so on. Although FIG. 1 shows the dies 115 stacked in a shingle stack (e.g., with die edges that are not aligned, which provides space for wire bonding near the edges of the dies 115), in some implementations, the dies 115 may be stacked in a different arrangement, such as a straight stack (e.g., with aligned die edges).

The apparatus 100 may include a casing 120 that protects internal components of the apparatus 100 (e.g., the integrated circuits 105) from damage and environmental elements (e.g., particles) that can lead to malfunction of the apparatus 100. The casing 120 may be a mold compound, a plastic (e.g., an epoxy plastic), a ceramic, or another type of material depending on the functional requirements for the apparatus 100.

In some implementations, the apparatus 100 may be included as part of a higher level system (e.g., a computer, a mobile phone, a network device, an SSD, a vehicle, or an Internet of Things device), such as by electrically connecting the apparatus 100 to a circuit board 125, such as a printed circuit board. For example, the substrate 110 may be disposed on the circuit board 125 such that electrical contacts 130 (e.g., bond pads) of the substrate 110 are electrically connected to electrical contacts 135 (e.g., bond pads) of the circuit board 125.

In some implementations, the substrate 110 may be mounted on the circuit board 125 using solder balls 140 (e.g., arranged in a ball grid array), which may be melted to form a physical and electrical connection between the substrate 110 and the circuit board 125. Additionally, or alternatively, the substrate 110 may be mounted on and/or electrically connected to the circuit board 125 using another type of connector, such as pins or leads. Similarly, an integrated circuit 105 may include electrical pads (e.g., bond pads) that are electrically connected to corresponding electrical pads (e.g., bond pads) of the substrate 110 using electrical bonding, such as wire bonding, bump bonding, or the like. The interconnections between an integrated circuit 105, the substrate 110, and the circuit board 125 enable the integrated circuit 105 to receive and transmit signals to other components of the apparatus 100 and/or the higher level system.

As shown in FIG. 1A, the apparatus 100 includes an ESD control system 145. The ESD control system 145 includes at least one ESD contact structure 150 that is electrically coupled to an integrated circuit (e.g., the integrated circuit 105-2 including the dies 115). In some implementations, the ESD contact structure 150 includes a first electrically-conductive material (e.g., copper). In a state of exposure to an environment surrounding the apparatus 100, the first electrically-conductive material may have a corrosion rate (e.g., millimeters per year) and/or an oxidation rate (mole per minute) that fails to satisfy a causticity threshold and effectuates undue damage and/or oxidation to the ESD contact structure 150. Additionally, or alternatively and in some implementations, the first electrically-conductive material may have a diffusion coefficient (e.g., square meters per volt-second) that fails to satisfy an electromigration threshold and effectuates undue movement of atoms and/or ions from the conductive material to prematurely degrade the ESD contact structure 150.

The ESD control system 145 further includes a protective barrier 155 that seals at least a portion of the ESD contact structure 150 from the environment. In some implementations, the protective barrier 155 conceals (e.g., obscures visible detection of) at least a portion of the ESD contact structure 150 along an outer sidewall 160 of the apparatus 100. Additionally, or alternatively and in some implementations, the ESD contact structure 150 is approximately flush with the outer sidewall 160 of the apparatus 100. Further, and in some implementations, the protective barrier 155 and the ESD contact structure 150 combine to form an electrical ground node of the ESD control system 145.

The protective barrier 155 may include a second electrically-conductive material. In some implementations, the second electrically-conductive material includes include a solder-based material. Alternatively, and in some implementations, the second electrically-conductive material includes an ink-based material.

A solder-based material is a material which contains solder, which is a low-melting-point metal alloy (e.g., a metal alloy that liquifies at less than 250 degrees Celsius) that is used to join or bond other metals together. The solder is applied in a molten state and solidifies upon cooling, creating a strong and conductive bond between the joined materials. For the protective barrier 155, the solder-based material (e.g., the second-electrically-conductive material) may be a tin-silver-copper alloy or a tin-copper-nickel alloy, among other examples.

An ink-based material is a material which contains a mixture of particulates, a liquid carrier and, in some implementations, a binder. The mixture is applied to a surface and cured, removing the liquid carrier to deposit a film containing the particulates and/or the binder on the surfaces. For the protective barrier 155, the ink-based material (e.g., the second-electrically-conductive material) may be a silver-based ink (e.g., an ink including silver particulates), a gold-based ink (e.g., an ink including gold particulates), a graphene-based ink (e.g., an ink including graphene particulates), or a polymer-carbon based ink (e.g., an ink including polymer-carbon particulates), among other examples.

In a state of exposure to an environment surrounding the apparatus 100, the second electrically-conductive material may have a corrosion rate and/or an oxidation rate that satisfies the causticity threshold (e.g., the corrosion and/or the oxidation rate of the second electrically-conductive material is less than the corrosion and/or the oxidation rate of the first electrically-conductive material). By sealing at least a portion of the ESD contact structure 150 from the environment, the protective barrier 155 may reduce a likelihood of damage and/or oxidation to the ESD contact structure 150.

Additionally, or alternatively and in some implementations, the second electrically-conductive material may have a diffusion coefficient that satisfies the electromigration threshold (e.g., the diffusion coefficient of the second electrically-conductive material is less than the diffusion coefficient of the first electrically-conductive material). By sealing at least a portion of the ESD structure 150 from the environment, the protective barrier 155 may reduce a likelihood of movement of atoms and/or ions from the ESD contact structure 150 to reduce a likelihood of premature degradation of the ESD contact structure 150.

As shown in FIG. 1A, the ESD control system 145 may further include an ESD distribution structure 165 (e.g., a pad structure, a ring structure) for routing and/or distributing an accumulated charge throughout the apparatus 100 and/or to the ESD contact structure 150. Additionally, or alternatively and as shown in FIG. 1, the ESD control system 145 may further include an interconnect structure 170 (e.g., a bond wire or a trace) that provides an electrically-conductive path between the integrated circuit 105 and the ESD distribution structure 165. Additionally, or alternatively and as shown in FIG. 1 as part of the ESD control system 145, the integrated circuit 105-2 including the dies 115 may include ESD protection circuitry 175. The ESD protection circuitry 175 may include a combination of diode devices and/or clamping devices that are configured to divert an accumulated electrostatic charge from the integrated circuit.

In some implementations, one or more structures and/or features of the ESD control system 145 may electrically couple with one another through one or more structures and/or other features. As an example, and in some implementations, the ESD protection circuitry 175 electrically couples with the protective barrier 155 through the ESD contact structure 150.

FIG. 1B shows an example layout (e.g., a top view) the apparatus 100 including the ESD control system 145. During manufacturing of the apparatus 100 (e.g., assembly and/or testing of the apparatus), the apparatus 100 may accumulate an electrostatic charge 180. The apparatus 100 (e.g., the ESD control system 145) may route and/or discharge the electrostatic charge 180 to an environment surrounding the apparatus 100. Routing and/or discharging the electrostatic charge 180 may include routing and/or discharging the electrostatic charge to an environment near the outer sidewall 160 through one or more of the ESD contact structure 150, the protective barrier 155, the ESD distribution structure 165, the interconnect structure 170, and/or the ESD protection circuitry 175.

As indicated above, FIGS. 1A and 1B are provided as an example. Other examples may differ from what is described with regard to FIGS. 1A and 1B.

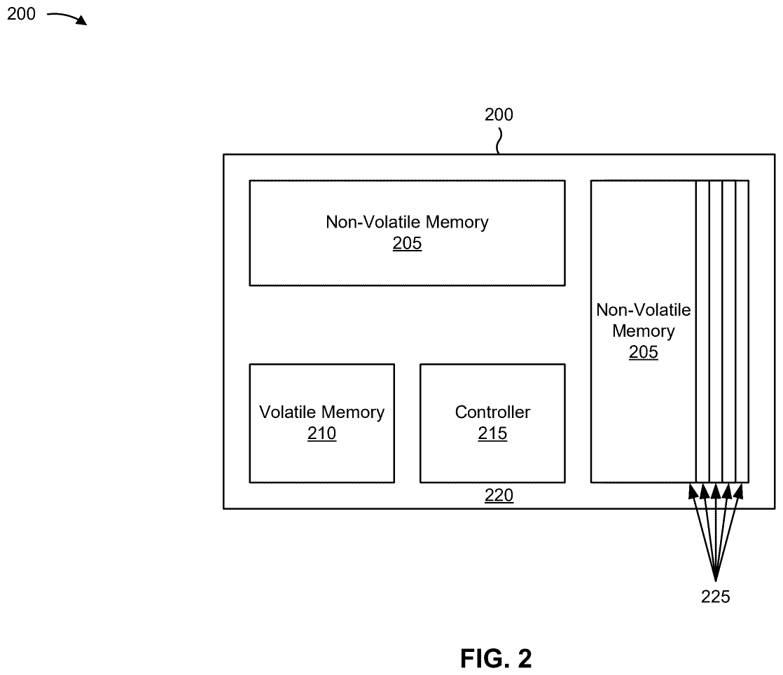

FIG. 2 is a diagram of an example memory device 200 that may be manufactured using techniques described herein. The memory device 200 is an example of the apparatus 100 described above in connection with FIG. 1. The memory device 200 may be any electronic device configured to store data in memory. In some implementations, the memory device 200 may be an electronic device configured to store data persistently in non-volatile memory 205. For example, the memory device 200 may be a hard drive, an SSD, a flash memory device (e.g., a NAND flash memory device or a NOR flash memory device), a universal serial bus (USB) thumb drive, a memory card (e.g., a secure digital (SD) card), a secondary storage device, a non-volatile memory express (NVMe) device, and/or an embedded multimedia card (eMMC) device.

As shown, the memory device 200 may include non-volatile memory 205, volatile memory 210, and a controller 215. The components of the memory device 200 may be mounted on or otherwise disposed on a substrate 220. In some implementations, the non-volatile memory 205 includes a single die. Additionally, or alternatively, the non-volatile memory 205 may include multiple dies, such as stacked semiconductor dies 225 (e.g., in a straight stack, a shingle stack, or another type of stack), as described above in connection with FIG. 1.

The non-volatile memory 205 may be configured to maintain stored data after the memory device 200 is powered off. For example, the non-volatile memory 205 may include NAND memory or NOR memory. The volatile memory 210 may require power to maintain stored data and may lose stored data after the memory device 200 is powered off. For example, the volatile memory 210 may include one or more latches and/or RAM, such as DRAM and/or SRAM. As an example, the volatile memory 210 may cache data read from or to be written to non-volatile memory 205, and/or may cache instructions to be executed by the controller 215.

The controller 215 may be any device configured to communicate with the non-volatile memory 205, the volatile memory 210, and a host device (e.g., via a host interface of the memory device 200). For example, the controller 215 may include a memory controller, a system controller, an ASIC, an FPGA, a processor, a microcontroller, and/or one or more processing components. In some implementations, the memory device 200 may be included in a system that includes the host device. The host device may include one or more processors configured to execute instructions and store data in the non-volatile memory 205.

The controller 215 may be configured to control operations of the memory device 200, such as by executing one or more instructions (sometimes called commands). For example, the memory device 200 may store one or more instructions as firmware, and the controller 215 may execute those one or more instructions. Additionally, or alternatively, the controller 215 may receive one or more instructions from a host device via a host interface, and may execute those one or more instructions. For example, the controller 215 may transmit signals to and/or receive signals from the non-volatile memory 205 and/or the volatile memory 210 based on the one or more instructions, such as to transfer data to (e.g., write or program), to transfer data from (e.g., read), and/or to erase all or a portion of the non-volatile memory 205 (e.g., one or more memory cells, pages, sub-blocks, blocks, or planes of the non-volatile memory 205).

In some implementations, one or more components of the memory device 200 (e.g., the non-volatile memory 205, the volatile memory 210, the controller 215, and/or the substrate 220) may include one or more components of an ESD protection system (e.g., the ESD control system 145 described in connection with FIG. 1).

As indicated above, FIG. 2 is provided as an example. Other examples may differ from what is described with regard to FIG. 2. The number and arrangement of components shown in FIG. 2 are provided as an example. In practice, there may be additional components, fewer components, different components, or differently arranged components than those shown in FIG. 2.

As described in connection with FIGS. 1A, 1B, and 2, and in some implementations, an apparatus (e.g., the apparatus 100 and/or the memory device 200) includes an integrated circuit (e.g., the integrated circuit 105), an ESD contact structure (e.g., the ESD contact structure 150) that is proximate to an outer edge (e.g., the outer sidewall 160) of the apparatus and that is electrically-coupled with the integrated circuit. The ESD contact structure includes a first material that is electrically-conductive and has a first corrosion rate in an environment surrounding the apparatus. The apparatus includes a protective barrier (e.g., the protective barrier 155) that is proximate to the ESD contact structure and that seals at least a portion of the ESD contact structure from the environment. The protective barrier includes a second material that is electrically-conductive and has a second corrosion rate in the environment that is less than the first corrosion rate.

Additionally, or alternatively and some implementations, a semiconductor device assembly (e.g., the apparatus 100 and/or the memory device 200) includes a semiconductor die (e.g., one of more of the dies 115), a casing (e.g., the casing 120) encapsulating the semiconductor die, and an ESD control system (e.g., the ESD control system 145). The ESD control system includes an ESD contact structure (e.g., the ESD contact structure 150) that is proximate to an outer sidewall (e.g., the outer sidewall 160) of the casing and includes a first material that is electrically-conductive and has a first diffusion coefficient. The ESD control system includes a protective barrier (e.g., the protective barrier 155) that is proximate to the ESD contact structure and that seals the ESD contact structure from an environment surrounding the casing. The protective barrier includes a second material that is electrically-conductive and has a second diffusion coefficient that is less than the first diffusion coefficient.

In this way, an ESD contact structure of a semiconductor package (e.g., the ESD contact structure 150 of the apparatus 100 and/or the memory device 200) is protected from corrosion (e.g., oxidation) and/or electromigration that may inhibit a capability of the ESD contact structure to discharge an accumulated electrostatic charge (e.g., the electrostatic charge 180) during assembly and/or handling of the semiconductor package. By protecting the ESD contact structure, a likelihood of damage to an IC device (e.g., the integrated circuits 105 and/or the dies 115) is reduced, to improve a quality and/or a reliability of the semiconductor package. As a result, an amount of resources used to support a market consuming the semiconductor package including the IC device (e.g., raw materials, labor, semiconductor manufacturing tools, and/or computing resources) is reduced.

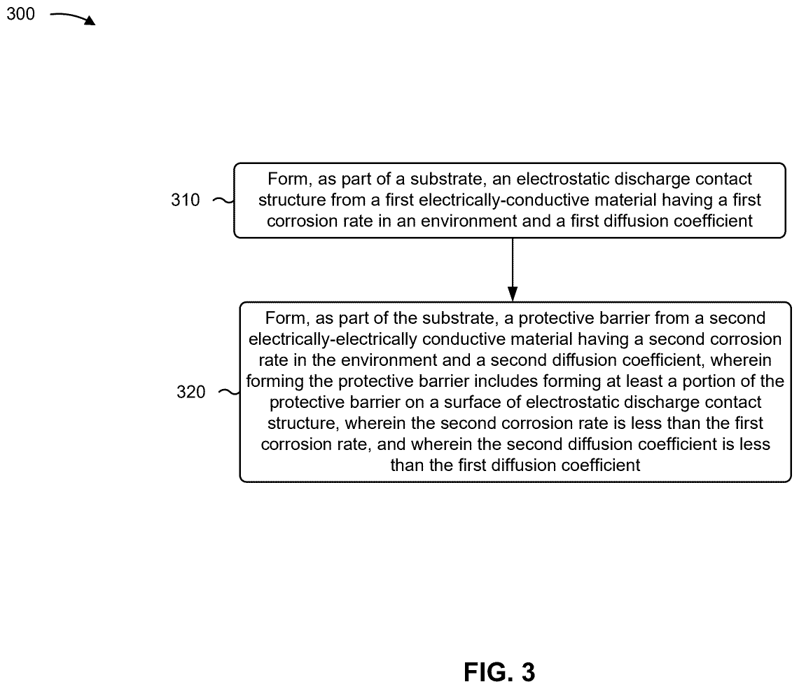

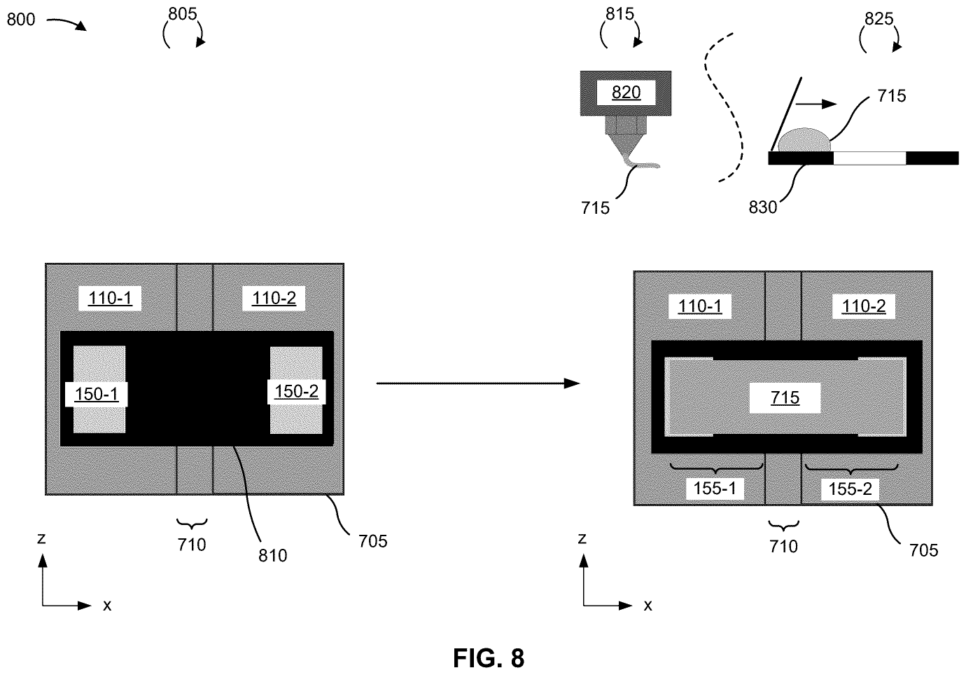

FIG. 3 is a flowchart of an example method 300 of forming a substrate (e.g., the substrate 100) having an ESD contact structure (e.g., the ESD contact structure 150) and a protective barrier (e.g., the protective barrier 155) described herein. In some implementations, and as described in greater detail in connection with FIG. 8, one or more process blocks of FIG. 3 may be performed by various semiconductor manufacturing equipment.

As shown in FIG. 3, the method 300 may include forming, as part of a substrate (e.g., the substrate 110), an ESD contact structure (e.g., the ESD contact structure 150) from a first electrically-conductive material having a first corrosion rate in an environment and a first diffusion coefficient (block 310). As further shown in FIG. 3, the method 300 may include forming, as part of the substrate, a protective barrier (e.g., the protective barrier 155) from a second electrically-conductive material having a second corrosion rate in the environment and a second diffusion coefficient, wherein forming the protective barrier includes forming at least a portion of the protective barrier on a surface of ESD contact structure, wherein the second corrosion rate is less than the first corrosion rate, and wherein the second diffusion coefficient is less than the first diffusion coefficient (block 320).

The method 300 may include additional aspects, such as any single aspect or any combination of aspects described below and/or in connection with one or more other methods described elsewhere herein.

In a first aspect, forming the protective barrier includes forming the protective barrier prior to forming an integrated circuit (e.g., the integrated circuit 105) on the substrate.

In a second aspect, alone or in combination with the first aspect, forming the protective barrier includes forming the protective barrier prior to forming a casing (e.g., the casing 120) around an integrated circuit (e.g., the integrated circuit 105) on the substrate.

In a third aspect, alone or in combination with one or more of the first and second aspects, forming the protective barrier includes forming the protective barrier through a solder mask opening in the substrate that exposes the ESD contact structure.

In a fourth aspect, alone or in combination with one or more of the first through third aspects, forming the protective barrier includes forming the protective barrier using a printing technique to print an ink-based material.

In a fifth aspect, alone or in combination with one or more of the first through fourth aspects, forming the protective barrier using the printing technique includes using a three-dimensional printing operation.

In a sixth aspect, alone or in combination with one or more of the first through fifth aspects, forming the protective barrier using the printing technique includes using an inkjet printing operation, using a screen-printing operation, using a flexographic printing operation, or using an offset printing operation.

In a seventh aspect, alone or in combination with one or more of the first through sixth aspects, forming the protective barrier includes forming the protective barrier using a solder deposition technique to deposit a solder-based material.

In an eighth aspect, alone or in combination with one or more of the first through seventh aspects, forming the protective barrier using the solder deposition technique includes using a selective soldering operation, using a reflow soldering operation, using a screen-printing operation, using an infrared soldering operation, or using an ultrasonic soldering operation.

In some implementations, one or more operations of the method 300 may be performed by one or more semiconductor manufacturing tools at a supplier that manufactures a substrate (e.g., the substrate 110) including the protective barrier for the ESD contact structure. Additionally, or alternatively and in some implementations, one or more operations of the method 300 may be performed by one or more semiconductor manufacturing tools at an outsource assembly and test (OSAT) supplier that assembles and/or tests the integrated assembly or memory device. Additionally, or alternatively and in some implementations, one or more of operations of the method 300 may be performed by one or more semiconductor manufacturing tools at an original equipment supplier (OEM) or contract manufacturer that assembles a system including the protective barrier for the ESD contact structure.

The method 300 may include additional aspects, such as any single aspect or any combination of aspects described below and/or described in connection with one or more other methods or operations described elsewhere herein.

Although FIG. 3 shows example blocks of the method 300, in some implementations, the method 300 may include additional blocks, fewer blocks, different blocks, or differently arranged blocks than those depicted in FIG. 3. In some implementations, the method 300 may include forming the protective barrier 155, an integrated assembly that includes the protective barrier 155, any part described herein of the protective barrier 155, and/or any part described herein of an integrated assembly that includes the protective barrier 155. For example, the method 300 may include forming one or more of the apparatus 100, the substrate 110, the ESD control system 145, the ESD contact structure 150, the ESD protection circuitry 175, and/or the memory device 200.

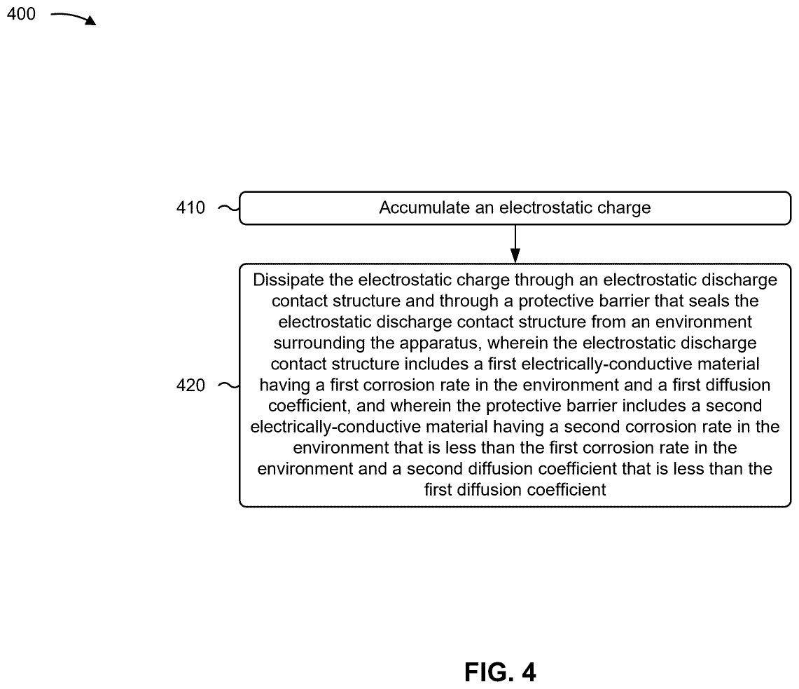

FIG. 4 is a flowchart of an example method 400 associated with a protective barrier (e.g., the protective barrier 155) for an ESD contact structure described herein. In some implementations, an apparatus (e.g., the apparatus 100) or memory device (e.g., the memory device 200) may perform or may be configured to perform the method 400. In some implementations, another device or a group of devices separate from or including the apparatus (e.g., the substrate 110, the ESD control system 145, the ESD contact structure 150, the ESD protection circuitry 175, and/or the memory device 200.) perform or may be configured to perform the method 400. Additionally, or alternatively, one or more components of the apparatus (e.g., the ESD control system 145, the ESD contact structure 150, the protective barrier 155, and/or the ESD protection circuitry 175) may perform or may be configured to perform the method 400. Thus, means for performing the method 400 may include the apparatus and/or one or more components of the apparatus. Additionally, or alternatively, a non-transitory computer-readable medium may store one or more instructions that, when executed by the apparatus, cause the apparatus to perform the method 400.

As shown in FIG. 4, the method 400 may include accumulating an electrostatic charge (e.g., the electrostatic charge 180) (block 410). As further shown in FIG. 4, the method 400 may include dissipating the electrostatic charge through an ESD contact structure (e.g., the ESD contact structure 150) and through a protective barrier (e.g., the protective barrier 155) that seals the ESD contact structure from an environment surrounding the apparatus, wherein the ESD contact structure includes a first electrically-conductive material having a first corrosion rate in the environment and a first diffusion coefficient, and wherein the protective barrier includes a second electrically-conductive material having a second corrosion rate in the environment that is less than the first corrosion rate in the environment and a second diffusion coefficient that is less than the first diffusion coefficient (block 420).

In some implementations, one or more operations of the method 400 may be performed by one or more semiconductor manufacturing tools at an OSAT supplier that assembles and/or tests the integrated assembly or memory device. Additionally, or alternatively and in some implementations, one or more of operations of the method 400 may be performed by one or more semiconductor manufacturing tools at an OEM or contract manufacturer that assembles a system including the protective barrier for the ESD contact structure.

The method 400 may include additional aspects, such as any single aspect or any combination of aspects described below and/or described in connection with one or more other methods or operations described elsewhere herein.

Although FIG. 4 shows example blocks of a method 400, in some implementations, the method 400 may include additional blocks, fewer blocks, different blocks, or differently arranged blocks than those depicted in FIG. 4. Additionally, or alternatively, two or more of the blocks of the method 400 may be performed in parallel. The method 400 is an example of one method that may be performed by one or more devices described herein. These one or more devices may perform or may be configured to perform one or more other methods based on operations described herein.

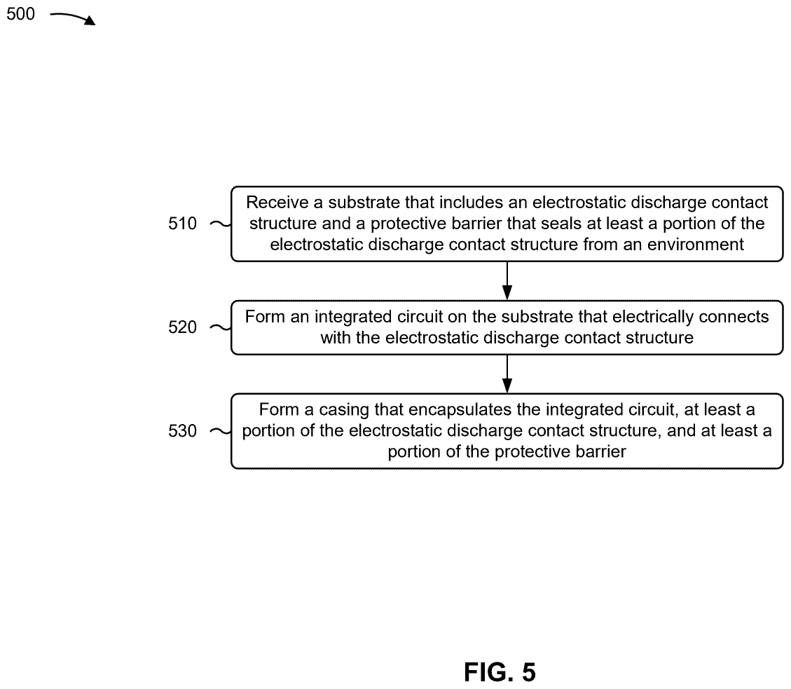

FIG. 5 is a flowchart of an example method 500 of forming a memory device (e.g., the memory device 200) having a protective barrier (e.g., the protective barrier 155) for an ESD contact structure (e.g., the ESD contact structure 150) described herein. In some implementations, one or more process blocks of FIG. 5 may be performed by various semiconductor manufacturing equipment.

As shown in FIG. 5, the method 500 may include receiving a substrate (e.g., the substrate 110) that includes an ESD contact structure (e.g., the ESD contact structure 150) and a protective barrier (e.g., the protective barrier 155) that seals at least a portion of the ESD contact structure from an environment (block 510). As further shown in FIG. 5, the method 500 may include forming an integrated circuit (e.g., the integrated circuit 105) on the substrate that electrically connects with the ESD contact structure (block 520). As further shown in FIG. 5, the method 500 may include forming a casing (e.g., the casing 120) that encapsulates the integrated circuit, at least a portion of the ESD contact structure, and at least a portion of the protective barrier (block 530).

In some implementations, one or more operations of the method 500 may be performed at an OSAT supplier that assembles and/or tests the integrated assembly or memory device. Additionally, or alternatively and in some implementations, one or more of operations of the method 500 may be performed at an OEM or contract manufacturer that assembles a system including the protective barrier for the ESD contact structure.

The method 500 may include additional aspects, such as any single aspect or any combination of aspects described below and/or described in connection with one or more other methods or operations described elsewhere herein.

Although FIG. 5 shows example blocks of the method 500, in some implementations, the method 500 may include additional blocks, fewer blocks, different blocks, or differently arranged blocks than those depicted in FIG. 3. In some implementations, the method 500 may include forming the protective barrier 155, an integrated assembly that includes the protective barrier 155, any part described herein of the protective barrier 155, and/or any part described herein of an integrated assembly that includes the protective barrier 155. For example, the method 500 may include forming one or more of the apparatus 100, the substrate 110, the ESD control system 145, the ESD contact structure 150, the ESD protection circuitry 175, and/or the memory device 200.

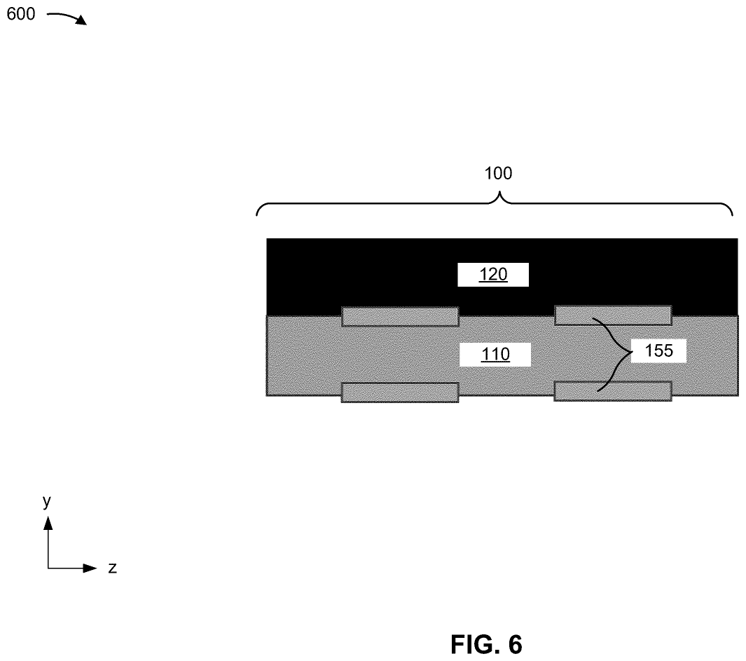

FIG. 6 is a diagram of an example implementation 600 of a protective barrier (e.g., the protective barrier 155) for an ESD contact structure (e.g., the ESD contact structure 150) described herein. The implementation 600 shows an example side view of the apparatus 100, the substrate 110, the casing 120, and a plurality of the protective barrier 155.

As shown in FIG. 6, and as part of implementation 600, configurations of the protective barrier 155 may span portions of the substrate 110 and/or the casing 120. In some implementations, the protective barrier 155 may fill (or partially fill) recesses and/or cavities within the substrate 110 and/or the casing 120 to conceal (e.g., obscure visible detection of) an ESD contact structure (e.g., the ESD contact structure 150) within the apparatus 100.

As indicated above, FIG. 6 is provided as an example. Other examples may differ from what is described with regard to FIG. 6.

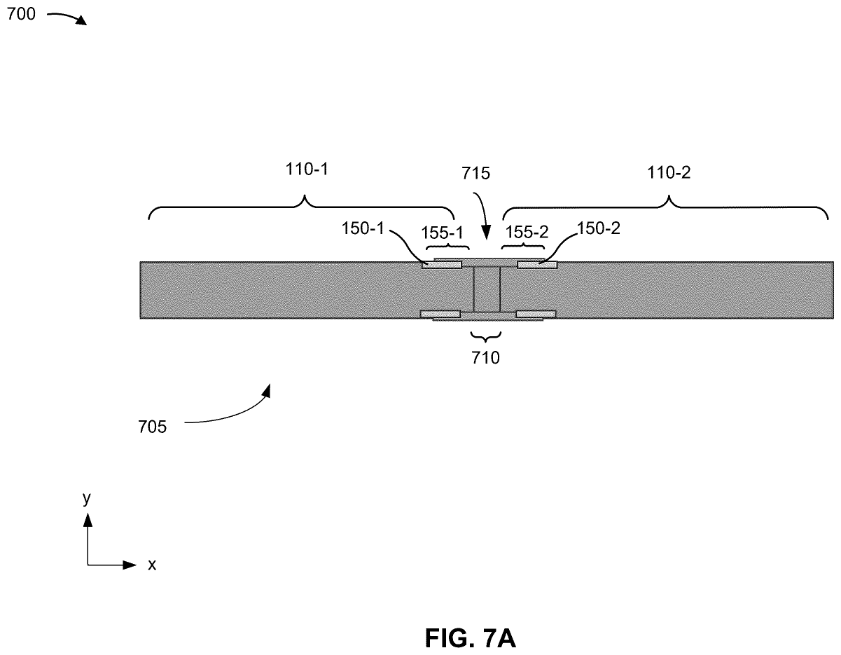

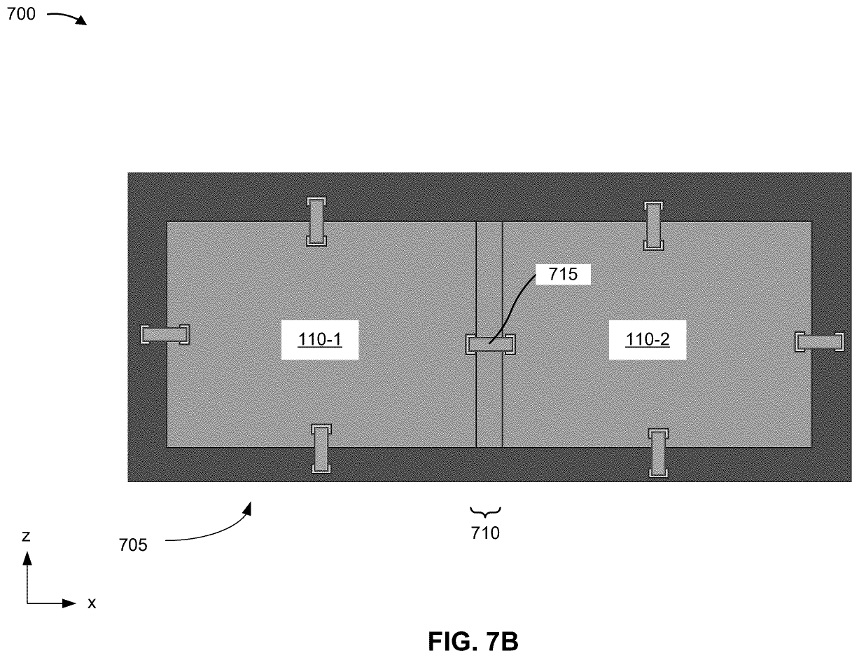

FIGS. 7A and 7B are diagrams of an example implementation 700 of a protective barrier (e.g., the protective barrier 155) for an ESD contact structure (e.g., the ESD contact structure 150) described herein. FIGS. 7A and 7B include a panel 705 (e.g., a printed circuit board (PCB) panel or an assembly strip) including at least one substrate 110. In some implementations, the panel 705 may be used in connection with the method 300 of FIG. 3, the method 400 of FIG. 4, and/or the method 500 of FIG. 5, among other examples.

As shown in the side view of FIG. 7A, the panel 705 includes the substrate 110-1 and the substrate 110-2. The substrate 110-1 includes the ESD contact structure 150-1. The substrate 110-2 includes the ESD contact structure 150-2. A scribe area 710 separates the substrate 110-1 and the substrate 110. In some implementations, the ESD contact structure 150-1 and/or the ESD contact structure 150-2 include a copper material. Additionally, or alternatively and in some implementations, the ESD contact structure 150-1 and/or the ESD contact structure 150-2 may include a gold material (e.g., gold plating as described in connection with FIG. 1).

As shown in FIG. 7A, and as described in greater detail in connection with FIG. 7B, FIG. 8, and elsewhere herein, an electrically-conductive material 715 is formed over within the scribe area 710 to join the ESD contact structure 150-1 and the ESD contact structure 150-2.

In some implementations, a semiconductor manufacturing operation (e.g., a dicing operation, a laser operation, a sawing operation) may remove the scribe area 710 to separate the substrate 110-1 and the substrate 110-2. In some implementations, the semiconductor manufacturing operation that separates the substrate 110-1 and the substrate 110-2 occurs after the substrate 110-1 and the substrate 110-2 are populated with integrated circuits (e.g., the integrated circuits 105 and/or the dies 115). Further, and in some implementations, the semiconductor manufacturing operation that separates the substrate 110-1 and the substrate 110-2 occurs after the integrated circuits are encapsulated (e.g., after the casing 120 is formed). After separation of the substrate 110-1 and the substrate 110-2, the protective barrier 155-1 and the protective barrier 155-2 may remain.

As shown in the top view of FIG. 7B, the panel 705 includes the substrate 110-1 and the substrate 110-2. Furthermore, FIG. 7B shows multiple instances of the electrically-conductive material 715 along perimeters and/or edges of the substrate 110-1 and the substrate 110-2.

As indicated above, FIGS. 7A and 7B are provided as an example. Other examples may differ from what is described with regard to Figs, 7A and 7B.

FIG. 8 includes an example series of semiconductor manufacturing operations 800 that may be performed to form a protective barrier (e.g., the protective barrier 155) for an ESD contact structure described herein. One or more of the series of semiconductor manufacturing operations 800 may correspond to one or more of the blocks described in connection with the method 300 of FIG. 3, the method 400 of FIG. 4, and/or the method 500 of FIG. 5, among other examples.

As shown in the top view of FIG. 8, and at operation 805, the panel 705 is received. The panel 705 (e.g., including the substrate 110-1, the substrate 110-2) includes a solder mask opening 810 that exposes the ESD contact structure 150-1 and the ESD contact structure 150-2.

In some implementations, and at operation 815, a printing technique is used to deposit the electrically-conductive material 715 in the solder mask opening 810 to form the protective barrier 115-1 and the protective barrier 155-2. In some implementations, the printing technique includes using a three-dimensional printing operation (e.g., an additive operation), during which a printing tool 820 sequentially deposits layers and/or three-dimensional patterns of the electrically-conductive material 715. Additionally, or alternatively, the printing technique may include using an inkjet printing operation, a screen-printing operation, a flexographic printing operation, or an offset printing operation, among other examples.

Alternatively, and in some implementations at operation 825, a solder deposition technique is used to deposit the electrically-conductive material 715 in the solder mask opening 810 to form the protective barrier 115-1 and the protective barrier 155-2. In some implementations, the solder-deposition technique includes using a screen-printing operation, during which a screen-printing tool 830 deposits the electrically-conductive material 715. Additionally, or alternatively, the solder deposition technique may include using a selective soldering operation, a reflow soldering operation, an infrared soldering operation, or an ultrasonic soldering operation, among other examples.

As indicated above, FIG. 8 is provided as an example. Other examples may differ from what is described with regard to FIG. 8.

Each of the illustrated x-axis, y-axis, and z-axis is substantially perpendicular to the other two axes. In other words, the x-axis is substantially perpendicular to the y-axis and the z-axis, the y-axis is substantially perpendicular to the x-axis and the z-axis, and the z-axis is substantially perpendicular to the x-axis and the y-axis. In some cases, a single reference number is shown to refer to a surface, or fewer than all instances of a part may be labeled with all surfaces of that part. All instances of the part may include associated surfaces of that part despite not every surface being labeled.

In some implementations, an apparatus includes an integrated circuit; an ESD contact structure that is proximate to an outer edge of the apparatus and that is electrically-coupled with the integrated circuit, comprising: a first material that is electrically-conductive and has a first corrosion rate in an environment surrounding the apparatus; and a protective barrier that is proximate to the ESD contact structure and that seals at least a portion of the ESD contact structure from the environment, comprising: a second material that is electrically-conductive and has a second corrosion rate in the environment that is less than the first corrosion rate.

In some implementations, a semiconductor device assembly includes a semiconductor die; a casing encapsulating the semiconductor die; and an electrostatic discharge control system, comprising: an ESD contact structure that is proximate to an outer sidewall of the casing, comprising: a first material that is electrically-conductive and has a first diffusion coefficient; and a protective barrier that is proximate to the ESD contact structure and that seals the ESD contact structure from an environment surrounding the casing, comprising: a second material that is electrically-conductive and has a second diffusion coefficient that is less than the first diffusion coefficient.

In some implementations, a method includes forming, as part of a substrate, an ESD contact structure from a first electrically-conductive material having a first corrosion rate in an environment and a first diffusion coefficient; and forming, as part of the substrate, a protective barrier from a second electrically-electrically-conductive material having a second corrosion rate in the environment and a second diffusion coefficient, wherein forming the protective barrier includes forming at least a portion of the protective barrier on a surface of ESD contact structure, wherein the second corrosion rate is less than the first corrosion rate, and wherein the second diffusion coefficient is less than the first diffusion coefficient.

In some implementations, a method includes accumulating, by an apparatus, an electrostatic charge; and dissipating, by the apparatus, the electrostatic charge through an ESD contact structure and through a protective barrier that seals the ESD contact structure from an environment surrounding the apparatus, wherein the ESD contact structure includes a first electrically-conductive material having a first corrosion rate in the environment and a first diffusion coefficient, and wherein the protective barrier includes a second electrically-conductive material having a second corrosion rate in the environment that is less than the first corrosion rate in the environment and a second diffusion coefficient that is less than the first diffusion coefficient.

The foregoing disclosure provides illustration and description but is not intended to be exhaustive or to limit the implementations to the precise forms disclosed. Modifications and variations may be made in light of the above disclosure or may be acquired from practice of the implementations described herein.

The orientations of the various elements in the figures are shown as examples, and the illustrated examples may be rotated relative to the depicted orientations. The descriptions provided herein, and the claims that follow, pertain to any structures that have the described relationships between various features, regardless of whether the structures are in the particular orientation of the drawings, or are rotated relative to such orientation. Similarly, spatially relative terms, such as “below,” “beneath,” “lower,” “above,” “upper,” “middle,” “left,” and “right,” are used herein for ease of description to describe one element's relationship to one or more other elements as illustrated in the figures. The spatially relative terms are intended to encompass different orientations of the element, structure, and/or assembly in use or operation in addition to the orientations depicted in the figures. A structure and/or assembly may be otherwise oriented (rotated 90 degrees or at other orientations), and the spatially relative descriptors used herein may be interpreted accordingly. Furthermore, the cross-sectional views in the figures only show features within the planes of the cross-sections, and do not show materials behind the planes of the cross-sections, unless indicated otherwise, in order to simplify the drawings.

As used herein, the terms “substantially” and “approximately” mean “within reasonable tolerances of manufacturing and measurement.” As used herein, “satisfying a threshold” may, depending on the context, refer to a value being greater than the threshold, greater than or equal to the threshold, less than the threshold, less than or equal to the threshold, equal to the threshold, not equal to the threshold, or the like.

Even though particular combinations of features are recited in the claims and/or disclosed in the specification, these combinations are not intended to limit the disclosure of implementations described herein. Many of these features may be combined in ways not specifically recited in the claims and/or disclosed in the specification. For example, the disclosure includes each dependent claim in a claim set in combination with every other individual claim in that claim set and every combination of multiple claims in that claim set. As used herein, a phrase referring to “at least one of”' a list of items refers to any combination of those items, including single members. As an example, “at least one of: a, b, or c” is intended to cover a, b, c, a+b, a+c, b+c, and a+b+c, as well as any combination with multiples of the same element (e.g., a+a, a+a+a, a+a+b, a+a+c, a+b+b, a+c+c, b+b, b+b+b, b+b+c, c+c, and c+c+c, or any other ordering of a, b, and c).

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Where only one item is intended, the phrase “only one,” “single,” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. As used herein, the term “multiple” can be replaced with “a plurality of” and vice versa. Also, as used herein, the term “or” is intended to be inclusive when used in a series and may be used interchangeably with “and/or,” unless explicitly stated otherwise (e.g., if used in combination with “either” or “only one of”).

What is claimed is:

1. An apparatus, comprising:
an integrated circuit;
an electrostatic discharge contact structure that is proximate to an outer edge of the apparatus and that is electrically-coupled with the integrated circuit, comprising:
a first material that is electrically-conductive and has a first corrosion rate in an environment surrounding the apparatus; and
a protective barrier that is proximate to the electrostatic discharge contact structure and that seals at least a portion of the electrostatic discharge contact structure from the environment, comprising:
a second material that is electrically-conductive and has a second corrosion rate in the environment that is less than the first corrosion rate.

2. The apparatus of claim 1, wherein the protective barrier coats at least a portion of a surface of the electrostatic discharge contact structure.

3. The apparatus of claim 1, further comprising:
a substrate, and
wherein the electrostatic discharge contact structure is proximate a surface of the substrate that faces toward the integrated circuit.

4. The apparatus of claim 1, further comprising:
a substrate, and
wherein the electrostatic discharge contact structure is proximate a surface of the substrate that faces away from the integrated circuit.

5. The apparatus of claim 1, wherein at least a portion of the electrostatic discharge contact structure is in a recess of a sidewall of the apparatus, and
wherein the protective barrier fills at least a portion of the recess.

6. The apparatus of claim 1, wherein an end of the electrostatic discharge contact structure is approximately flush with a sidewall of the apparatus, and
wherein the protective barrier coats the end of the electrostatic discharge contact structure.

7. The apparatus of claim 1, wherein the protective barrier comprises:
a solder-based material.

8. The apparatus of claim 7, wherein the solder-based material comprises:
a tin-silver-copper alloy, or
a tin-copper-nickel alloy.

9. The apparatus of claim 1, wherein the protective barrier comprises:
an ink-based material.

10. The apparatus of claim 9, wherein the ink-based material comprises:
a silver-based ink,
a gold-based ink,
a graphene-based ink,
a platinum-based ink, or
a polymer-carbon-based ink.

11. A semiconductor device assembly, comprising:
a semiconductor die;
a casing encapsulating the semiconductor die; and
an electrostatic discharge control system, comprising:
an electrostatic discharge contact structure that is proximate to an outer sidewall of the casing, comprising:
a first material that is electrically-conductive and has a first diffusion coefficient; and
a protective barrier that is proximate to the electrostatic discharge contact structure and that seals the electrostatic discharge contact structure from an environment surrounding the casing, comprising:
a second material that is electrically-conductive and has a second diffusion coefficient that is less than the first diffusion coefficient.

12. The semiconductor device assembly of claim 11, wherein the electrostatic discharge control system further comprises:
electrostatic discharge protection circuitry on the semiconductor die,
wherein the electrostatic discharge protection circuitry electrically couples with the protective barrier through the electrostatic discharge contact structure.

13. The semiconductor device assembly of claim 11, wherein the electrostatic discharge contact structure and the protective barrier combine to form an electrical ground node for the electrostatic discharge control system.

14. The semiconductor device assembly of claim 11, wherein the protective barrier conceals the electrostatic discharge contact structure along the outer sidewall of the casing.

15. The semiconductor device assembly of claim 11, wherein the electrostatic discharge contact structure comprises:
a gold plating,
a gold-silver alloy plating,
a gold-nickel alloy plating,
a gold-cobalt alloy plating, or
a gold-platinum alloy plating.

16. A method, comprising:
forming, as part of a substrate, an electrostatic discharge contact structure from a first electrically-conductive material having a first corrosion rate in an environment and a first diffusion coefficient; and
forming, as part of the substrate, a protective barrier from a second electrically-electrically-conductive material having a second corrosion rate in the environment and a second diffusion coefficient,
wherein forming the protective barrier includes forming at least a portion of the protective barrier on a surface of electrostatic discharge contact structure,
wherein the second corrosion rate is less than the first corrosion rate, and
wherein the second diffusion coefficient is less than the first diffusion coefficient.

17. The method of claim 16, wherein forming the protective barrier includes:
forming the protective barrier prior to forming an integrated circuit on the substrate.

18. The method of claim 16, wherein forming the protective barrier includes:
forming the protective barrier prior to forming a casing around an integrated circuit on the substrate.

19. The method of claim 16, wherein forming the protective barrier includes:
forming the protective barrier through a solder mask opening in the substrate that exposes the electrostatic discharge contact structure.

20. The method of claim 16, wherein forming the protective barrier includes:
forming the protective barrier using a printing technique to print an ink-based material.

21. The method of claim 20, wherein forming the protective barrier using the printing technique includes:
using a three-dimensional printing operation.

22. The method of claim 20, wherein forming the protective barrier using the printing technique includes:
using an inkjet printing operation,
using a screen-printing operation,
using a flexographic printing operation, or
using an offset printing operation.

23. The method of claim 16, wherein forming the protective barrier includes:
forming the protective barrier using a solder deposition technique to deposit a solder-based material.

24. The method of claim 23, wherein forming the protective barrier using the solder deposition technique includes:
using a selective soldering operation,
using a reflow soldering operation,
using a screen-printing operation,
using an infrared soldering operation, or
using an ultrasonic soldering operation.

25. A method, comprising:
accumulating, by an apparatus, an electrostatic charge; and
dissipating, by the apparatus, the electrostatic charge through an electrostatic discharge contact structure and through a protective barrier that seals the electrostatic discharge contact structure from an environment surrounding the apparatus,
wherein the electrostatic discharge contact structure includes a first electrically-conductive material having a first corrosion rate in the environment and a first diffusion coefficient, and
wherein the protective barrier includes a second electrically-conductive material having a second corrosion rate in the environment that is less than the first corrosion rate in the environment and a second diffusion coefficient that is less than the first diffusion coefficient.
